(19) United States
(12) Patent Application Publication
(10) Pub. No.: US 2025/0383410 A1
(43) Pub. Date: Dec. 18, 2025

(54) A SYSTEM AND AN ASSAY METHOD FOR DETECTION AND IDENTIFICATION OF ELEMENTARY PARTICLES

(71) Applicant: Sharon Aradine, San Antonio, TX (US)

(72) Inventor: Sharon Aradine, San Antonio, TX (US)

(21) Appl. No.: 18/820,742

(22) Filed: Aug. 30, 2024

Related U.S. Application Data
(60) Provisional application No. 63/552,944, filed on Feb. 13, 2024.

(51) Int. Cl. G01R 33/00; G01R 29/12

(52) U.S. Cl. CPC G01R 33/0023; G01R 29/12

(57) ABSTRACT

The present disclosure discloses a system and an assay method for detection and identification of elementary particles. The method includes receiving a signal including an electromagnetic particle and a quantum field. The signal includes a wave cycle with elementary particles. The method includes generating a first wave cycle based on the wave cycle and a second wave cycle by interaction of the wave cycle and the first wave cycle with the quantum field. The method includes identifying a first set of three amplitudes of the wave cycle and a second set of three amplitudes of the first wave cycle based on the second wave cycle and the interaction of the first wave cycle and the quantum field. The method includes identifying an elementary particle from each amplitude of the first set of three amplitudes of the wave cycle and the second set of three amplitudes of the first wave cycle.

### TECHNICAL FIELD

The present disclosure relates to a field of quantum mechanics and particle physics, and more particularly, relates to a system and a method to identify elementary particles in a wave cycle for understanding wave-particle and field interactions and behaviors at a quantum level.

### BACKGROUND

The field of quantum mechanics has long grappled with the fundamental nature of matter and energy at the smallest scales. Central to this field is the concept of wave-particle duality, which proposes that elementary particles exhibit both wave-like and particle-like properties. Despite significant advancements, there is a well-established need to understand detailed mechanisms of how quantum interactions affect all larger systems that arise from the quantum realm.

Conventional mechanisms of quantum mechanics, while successful in predicting various phenomena, often present limitations in explaining certain aspects of particle behavior and interactions. For instance, the Standard Model of particle physics, though comprehensive, does not provide a clear understanding regarding the nature of dark matter, the unification of fundamental forces, and the reconciliation of quantum mechanics with general relativity. The Standard Model categorizes elementary particles into fermions (such as quarks), bosons (force carriers), and leptons, each particle having attributes such as mass, charge, and spin.

Further, the mathematical complexity of conventional quantum theory often necessitates simplifications and approximations, which can limit the accuracy and scope of its predictions. This is particularly evident in the study of multi-particle systems and high-energy particle interactions, where the interactions become increasingly complex and difficult to understand.

Furthermore, in the fields of science, technology, engineering, and mathematics, there is a continuous need for more refined and accurate models that can predict particle behaviors in various contexts, such as in semiconductor technology, materials science, medicine, and nanotechnology, but not limited to the like. Improved models are crucial for the development of new materials and technologies, especially those operating at and beyond the quantum level.

Additionally, the field of computational physics faces challenges in simulating quantum phenomena accurately due to the inherent limitations of existing theoretical models. Enhanced models that more accurately capture the nuances of wave-particle interactions can lead to more precise simulations and, consequently, better experimental and technological outcomes.

Therefore, there exists a well-established and technological need for an improved mechanism or framework for analyzing interactions, properties, and behaviors of the most fundamental constituents of matter, for advancements in various technological and scientific fields.

### SUMMARY

Various embodiments of the present disclosure relate to systems and methods for analyzing at least one elementary particle in a wave cycle of an electromagnetic particle generated by an apparatus for understanding the wave-particle interactions and behaviors at a quantum level.

Various aspects of the present invention relate to an assay method for identifying at least one elementary particle generated in an apparatus. The assay method includes steps of receiving a signal including at least an electromagnetic particle and a quantum field (also referred to as a “quantum field fluctuation”) from the apparatus. The signal includes two elementary waves, which can be further broken down into smaller components. The elementary waves includes three amplitudes that comprise the wave cycle, with each amplitude further comprised of particles from the Standard Model. The assay method further includes generating additional waves by mechanisms of constructive and destructive interferences to both coherent and decoherent waves. The assay method further includes identifying the at least one elementary particle from the at least three amplitudes of the wave cycle and the first wave cycle based on the second wave cycle in the first set of elementary particles and the second set of elementary particles based on principles of wave mechanics. The at least one elementary wave includes at least one of a fermion, a set of bosons, and a set of leptons.

Various aspects of the present invention relate to an assay method for identifying at least one elementary particle generated in an apparatus. The assay method includes steps of receiving a signal including at least one of an electromagnetic particle and a quantum field from the apparatus. The signal further includes at least one elementary wave cycle (also referred to as “at least one wave cycle”). The at least one elementary wave cycle includes at least first set of three amplitudes. The at least one elementary particle in each amplitude of the at least first set of three amplitudes comprising at least one first set of elementary particles. The assay method further includes generating a first wave cycle comprising at least second set of three amplitudes based on the wave cycle. The at least one elementary particle in each amplitude of the at least second set of three amplitudes comprising at least one second set of elementary particles. The assay method further includes generating a second wave cycle by interaction of at least one of the wave cycle and the first wave cycle with the quantum field. The assay method further includes identifying the at least first set of three amplitudes of the wave cycle and the at least second set of three amplitudes of the first wave cycle based on at least one of the second wave cycle and the interaction of the first wave cycle and the quantum field. The assay method further includes identifying the at least one elementary particle from each amplitude of the at least first set of three amplitudes of the wave cycle and each amplitude of the at least second set of three amplitudes of the first wave cycle in the first set of elementary particles and the second set of elementary particles based on wave mechanics. The at least one elementary wave includes at least one of a fermion, a set of bosons, and a set of leptons. The set of leptons include at least one of an electron, a positron, amuon, an anti-muon, a tau, and an anti-tau particle.

In another aspect, the present invention relates to a system having an apparatus including a particle source, a detector, and a transmitter, the particle source is configured to generate at least on of an electromagnetic particle and a quantum field (also referred to as “a quantum field fluctuation”) in a predefined orientation; and an analysis unit. The analysis unit includes a memory for storing instructions, a control unit, and a processor. The control unit is equipped with a display controller, a display unit, a non-volatile storage unit, an input/output (I/O) controller and one or more I/O devices. The processor is configured for executing the instructions, the processor to receive a signal that includes at least one of the electromagnetic particle and the quantum field from the apparatus, the signal including at least one wave cycle with at least first set of three amplitudes. The at least one elementary particle in each amplitude of the at least first set of three amplitudes having at least one of a first set of elementary particles. The processor is further configured to cause the system, at least in part, generate a first wave cycle with at least second set of three amplitudes based on the wave cycle. The at least one elementary particle in each amplitude of the at least second set of three amplitudes having at least one of a second set of elementary particles. The processor is further configured to generate a second wave cycle by interaction of at least one of the wave cycle and the first wave cycle with the quantum field. This process can further elicit new systems of particles, or manipulate the underlying quantum field (or quantum fields) to give rise to specific fluctuations resulting in particle detection and identification. The processor is further configured to identify at least first set of three amplitudes of the wave cycle and at least second set of three amplitudes of the first wave cycle based on at least one of the second wave cycle and the interaction of the first wave cycle with the quantum field. The processor is further configured to identify at least one elementary particle from the at least first set of three amplitudes of the wave cycle and the at least second set of three amplitudes of the first wave cycle based on the second wave cycle in the first set of elementary particles and the second set of elementary particles based on wave mechanics. The at least one elementary particle includes but is not limited to at least one of a fermion, a set of bosons, and a set of leptons. The set of leptons includes at least one of an electron, a positron, a muon, an anti-muon, a tau, and an anti-tau particle.

### BRIEF DESCRIPTION OF THE FIGURES

The following detailed description of illustrative embodiments is better understood when read in conjunction with the appended drawings. To illustrate the present disclosure, exemplary constructions of the disclosure are shown in the drawings. However, the present disclosure is not limited to a specific device, or a tool and instrumentalities disclosed herein. Moreover, those in the art will understand that the drawings are not to scale.

FIG. 1 illustrates a schematic diagram of a system for detecting and identifying elementary particles and quantum field interactions in at least one wave cycle of an electromagnetic particle, in accordance with an exemplary embodiment of the present disclosure;

FIG. 2 illustrates representations of different views of example waves in the at least one wave cycle, in accordance with some exemplary embodiments of the present disclosure;

FIG. 3 illustrates the at least one wave cycle reflected across X-axis and Z-axis, in accordance with some exemplary embodiments of the present disclosure;

FIG. 4 illustrates a representation of wave interference of at least two waves, in accordance with some embodiments of the present disclosure;

FIG. 5 illustrates a representation of constructive and destructive interference that occurs due to rebound off a predicted underlying quantum field, in accordance with some embodiments of the present disclosure;

FIG. 6 illustrates a representation of a wave cycle with constructive interference of the wave cycle and the first wave cycle, in accordance with embodiments of the present disclosure;

FIG. 7 illustrates a representation of a wave cycle with destructive interference of the wave cycle and the first wave cycle, in accordance with embodiments of the present disclosure;

FIG. 8 illustrates representation of an electromagnetic particle associated with the wave cycle and a first wave cycle, in accordance with some embodiments of the present disclosure;

FIG. 9 illustrates a representation of elementary quark particles and their symmetric counterparts present in the wave cycle and the first wave cycle, in accordance with some embodiments of the present disclosure;

FIG. 10 illustrates a representation of z-axis of one full cycle of the wave cycle having positive amplitude, in accordance with embodiments of the present disclosure;

FIG. 11 illustrates a representation of z-axis of one full cycle of the first wave cycle having negative amplitude, in accordance with embodiments of the present disclosure; and

FIG. 12 illustrates a schematic flowchart of an assay method for detection and identification of at least one elementary particle, in accordance with an embodiment of the present disclosure.

The drawings referred to in this description are not to be understood as being drawn to scale except if specifically noted, and such drawings are only exemplary in nature.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details. Descriptions of well-known components and processing techniques are omitted to not unnecessarily obscure the embodiments herein. The examples used herein are intended merely to facilitate an understanding of ways in which the embodiments herein may be practiced and to further enable those skilled in the art to practice the embodiments herein. Accordingly, the examples should not be construed as limiting the scope of the embodiments herein.

Reference in this specification to “one embodiment” or “an embodiment” means that a particular feature, structure, or characteristic described in connection with the embodiment is included in at least one embodiment of the present disclosure. The appearances of the phrase “in an embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

Various examples of the present disclosure provide a characterization of wave-like and particle-like properties of elementary particles such as quarks, bosons, electrons, tau particles, and muons in at least one wave cycle of an electromagnetic particle.

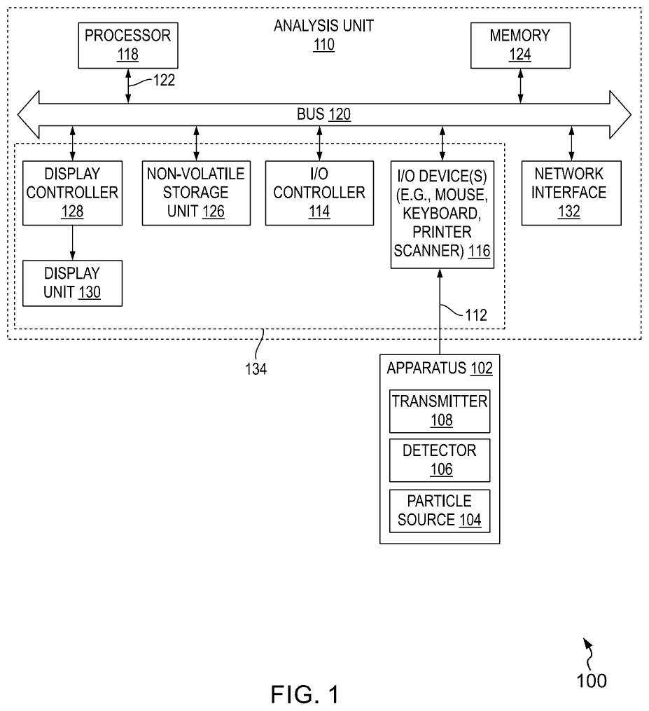

Various embodiments of the present invention are described hereinafter with reference to FIG. 1 to FIG. 12.

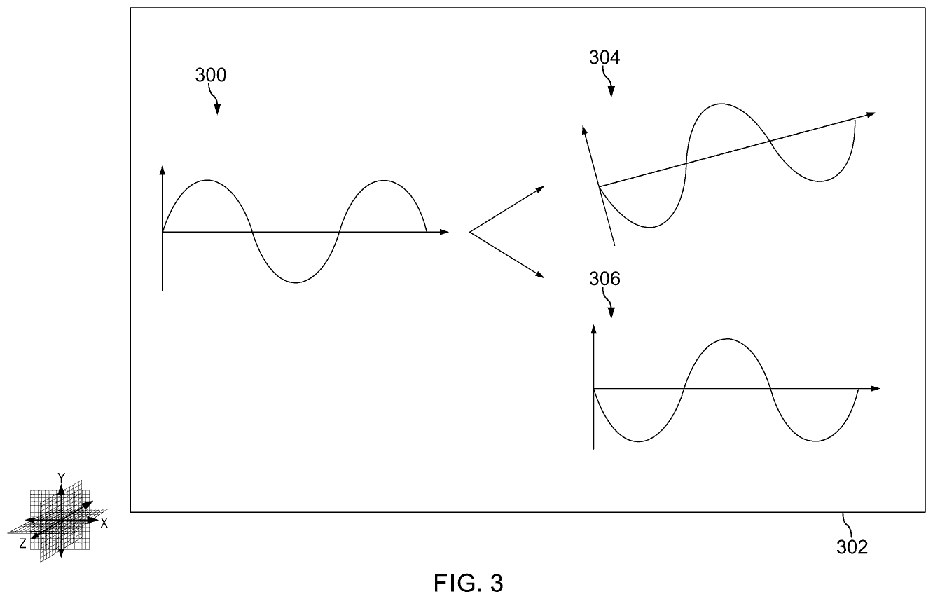

FIG. 1 illustrates a schematic representation of a system 100 for detecting and identifying elementary particles in at least one wave cycle of a signal received from an apparatus 102. The signal includes at least one of an electromagnetic particle and a quantum field (e.g., Higgs field), in accordance with an exemplary embodiment of the present disclosure. The system 100 has an apparatus 102, and an analysis unit 110. The apparatus 102 is configured to generate the signal including at least one of an electromagnetic particle and a quantum field (also referred to as “a quantum field fluctuation”) in a predictable and predefined orientation (302, shown in FIG. 3, or maybe figure with the large dataset as discussed later) and the analysis unit 110 is configured for detecting and identifying at least one elementary particle in the signal. The analysis unit 110 includes a processor 118, a memory 114, a network interface 132, and a control unit 134. In an embodiment, the apparatus 102 includes a particle source 104, a detector 106, and a transmitter 108. In an embodiment, the particle source 104 may be, but is not limited to, a light source, an acoustic source, or any other vibrational source (e.g., a wind source causing water waves). Further, the particle source 104 is a continuous wave particle source configured to produce at least one of an electromagnetic particle and a quantum field in the form of one or more pulses in a wavelength region. The one or more pulses may include at least one of a photon, a gluon, and a set of new particles.

In an embodiment, the detector 106 may be, but is not limited to, a photodetector or an acoustic detector, or any other detector capable of detecting frequency and vibrational waves resulting from the movement of the electromagnetic particle on interaction with the underlying quantum field. The detector 106 is configured to convert the at least one wave cycle contained within a defined radius associated with the at least one of the electromagnetic particle and the quantum field into an electronic detection signal correlated to the one or more pulses.

In an embodiment, the control unit 134 is equipped with one or more controllers. For instance, the control unit 134 may include a display controller 128, a display unit 130, a non-volatile storage unit 126, an input/output (I/O) controller 114, and one or more I/O devices 116. The control unit 134 controls the input/output and display operations of the system 100 based on the information received from the transmitter 108 of the apparatus 102. In an instance, the transmitter 108 coupled to the detector 106 is configured to transmit, in a flow, the electronic detection signal in the form of a wave cycle input 112 (also referred to as the signal) to the I/O controller 114 of the control unit 134.

The control unit 134 can be a standalone component operating apart from the system 102 for controlling operations of the system 100. However, in other embodiments, the control unit 134 may be incorporated, in whole or in part, into one or more parts of the system 100, for example, the analysis unit 110. Further, the control unit 134 should be understood to be embodied in at least one computing device which may be specifically configured, via executable instructions, to perform as described herein, and/or embodied in at least one non-transitory computer-readable media.

In an embodiment, the non-volatile storage unit 126 coupled with a network interface 132 is accessible to the processor 118 for data processing. The non-volatile storage unit 126 (also referred to as the storage unit 126) connected to a bus 120 is configured to store information about the wave cycle input 112 provided by the I/O controller 114. The non-volatile storage unit 126 may also be configured to store data about the wave particle interaction points, the magnitude of electrical and magnetic forces, radian values of associated wave cycle components such as cycle wavelength, cycle time period, and amplitude, and the like. The storage unit 126 may be maintained by a third party or embodied within the system 100. The storage unit 126 may itself include multiple storage units, such as hard disks and/or solid-state disks in a Redundant Array of Inexpensive Disks (RAID) configuration. The storage unit 126 may also include a Storage Area Network (SAN) and/or a Network Attached Storage (NAS) system. The network interface 132 may include, without limitation, satellite transmission interface or other interfaces coupled to the control unit 134 or coupling the processor 118 to processor(s) of other data processing systems. The network interface 132 may be connected to a network that may include, a light fidelity (Li-Fi) network, a Local Area Network (LAN), a Wide Area Network (WAN), a Metropolitan Area Network (MAN), a satellite network, the Internet, a fiber-optic network, a coaxial cable network, an infrared (IR) network, a Radio Frequency (RF) network, a virtual network, and/or another suitable public and/or private network capable of supporting communication among the entities illustrated in FIG. 1, or any combination thereof.

In an embodiment, the input/output (I/O) controller 114 is configured to receive the wave cycle input 112 from the transmitter 108 of the apparatus 102 through the one or more I/O devices 116 and send information to the processor 118 for data processing. The display controller 128 is configured to receive the wave cycle output 122 from the processor 118. In one embodiment, the display controller 128 is configured to receive the wave cycle output 122 from the processor 118 through the one or more I/O devices 116. The one or more I/O devices 116 may include, but are not limited to, a keyboard, a mouse, a printer, a scanner, and the like.

In an embodiment, the display controller 128 is configured to display the wave cycle output 122 in the display unit 130 (e.g., a Cathode Ray Tube (CRT) or a Liquid Crystal Display (LCD), or a Light emitting diode (LED), etc.).

The processor 118 includes suitable logic, circuitry, and/or interfaces to execute computer-readable instructions for classifying and determining fraudulent activities in the network interface 132, etc. Examples of the processor 118 include, but are not limited to, an Application-Specific Integrated Circuit (ASIC) processor, a reduced instruction set computing (RISC) processor, a Complex Instruction Set Computing (CISC) processor, a Graphical Processing Unit (GPU) processor, a Field-Programmable Gate Array (FPGA), and the like.

The processor 118 is configured for executing the instructions that can be used to store software and data which when executed by a data processing system causes the system 100 to perform various methods described herein. This executable software and data may be stored in the memory unit in form of computer readable instructions. The memory 124 includes suitable logic, circuitry, and/or interfaces to store a set of computer-readable instructions for performing operations. Examples of the memory 124 include a Random-Access Memory (RAM), a Read-Only Memory (ROM), a removable storage drive, a Hard Disk Drive (HDD), and the like. It will be apparent to a person skilled in the art that the scope of the disclosure is not limited to realizing the memory 124 in the analysis unit 110, as described herein. In another embodiment, the memory 124 may be realized in the form of a database server or cloud storage working in conjunction with a server system, without departing from the scope of the present disclosure.

In an embodiment, the processor 118 causes the system 100, at least in part, to generate a first wave cycle (306, shown in FIG. 3) from the at least one wave cycle 300 in the electromagnetic particle (302, shown in FIG. 3). The at least one of the electromagnetic particle and the quantum field includes at least one wave cycle with at least one elementary particle, which can be further broken into smaller components. The at least one elementary wave cycle includes at least first set of three amplitudes, with each amplitude further including at least one elementary particle from a Standard Model. The Standard Model categorizes elementary particles into fermions (such as quarks), bosons (force carriers), and leptons, each particle having attributes such as mass, charge, and spin. The wave cycle 300 (in the predetermined orientation, for example, positive wave) has a first set of elementary particles and the first wave cycle 306 (in the predetermined orientation, for example, negative wave) has a second set of elementary particles. In some embodiments, the predetermined orientation includes but is not limited to at least one of the positive wave and the negative wave. Consequently, the processor 118 causes the system 100 to generate a second wave cycle (not shown in FIG. 3) by interaction of at least one of the wave cycle and the first wave cycle with the quantum field. Further, the processor 118 identifies the at least first set of three amplitudes of the wave cycle and the at least second set of three amplitudes of the first wave cycle based on at least one of the second wave cycle and the interaction of the first wave cycle and the quantum field. The processor 118 identifies at least one elementary particle from each amplitude of the at least first set of three amplitudes of the wave cycle and the at least second set of three amplitudes of the first wave cycle in the first set of elementary particles and the second set of elementary particles based on wave mechanics. The at least one elementary particle includes at least one of a fermion, a set of bosons, and a set of leptons. The set of leptons includes at least one of an electron, a positron, a muon, an anti-muon, a tau, and an anti-tau particle.

In an embodiment, the processor 118 further causes the system 100, at least in part, to determine energy levels and interaction points of the first set of elementary particles and the second set of elementary particles by mapping each of the first set of elementary particles to positions on the wave cycle 300 and mapping each of the second set of elementary particles to positions on the first wave cycle 306. Mapping also is guided by the underlying dataset as described later. The processor 118 further causes the system 100 to measure magnitudes of electrical and magnetic forces and quantum fields resulting from the interaction with the quantum field. Moreover, the processor 118 causes the system 100 to determine wave mechanics in the second wave cycle based on the magnitudes of electrical and mechanical forces measured.

The number and arrangement of systems, devices, and/or networks shown in FIG. 1 are provided as an example. There may be additional systems, devices, and/or networks; fewer systems, devices, and/or networks; different systems, devices, and/or networks; and/or differently arranged systems, devices, and/or networks than those shown in FIG. 1. Furthermore, two or more systems or devices shown in FIG. 1 may be implemented within a single system or device, or a single system or device shown in FIG. 1 may be implemented as multiple, distributed systems or devices. Additionally, or alternatively, a set of systems (e.g., one or more systems) or a set of devices (e.g., one or more devices) of the system 100 may perform one or more functions described as being performed by another set of systems or another set of devices of the system 100.

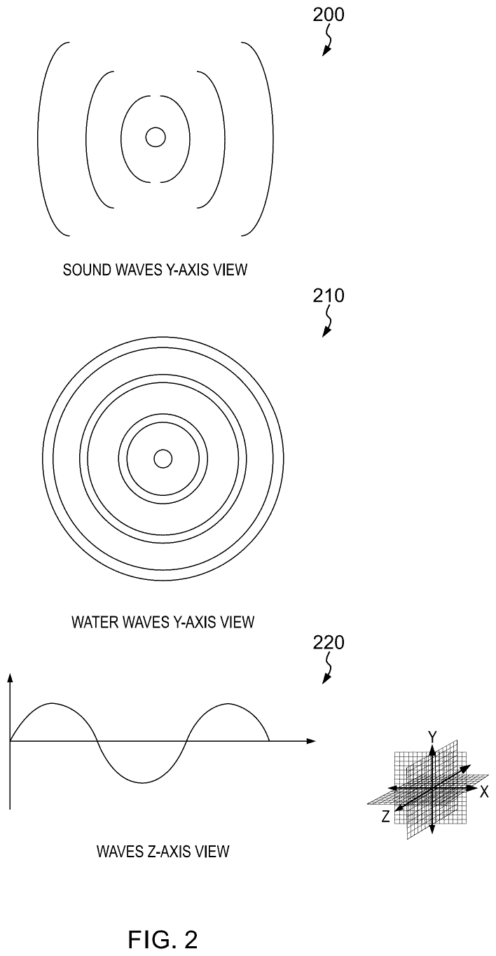

FIG. 2 illustrates representations 200, 210, and 220 of different views of example waves in the at least one wave cycle, in accordance with some exemplary embodiments of the present disclosure. The waves can be, but not limited to sound waves, water waves, and the like. As shown, the axes X, Y and Z are labeled with respective arrows indicating the positive direction for each axis, thereby establishing a basis for interpreting subsequent embodiments as discussed hereinafter. The representation 200 depicts the sound wave in the Y-axis view, the representation 210 depicts the water wave in the Y-axis view, and the representation 220 depicts of a positive wave in the Z-axis view.

FIG. 3 illustrates the at least one wave cycle 300 reflected across X-axis and Z-axis, in accordance with some exemplary embodiments of the present disclosure. The at least one wave cycle 300 represents a sine wave of positive amplitude. The at least one wave cycle 300 is being reflected across the Z and X axes by the analysis unit 110 of FIG. 1, to generate a Z-axis wave 304 and an X-axis wave (i.e., the first wave cycle 306) respectively. The Z-axis wave 304 and X-axis wave (i.e., the first wave cycle 306) depend on the at least one wave cycle 300, and are collectively referred to as at least one first wave with at least one first wave cycle.

The X-axis reflection (see, 306) results in a distinct separate wave (the negative wave or the Yin Wave), while the Z-axis reflection (see, 304) results in a distinct separate wave (anti-matter). The wave cycle 300 represents the positive-amplitude sine wave and includes the first set of elementary particles. In an explanatory embodiment, the at least one wave cycle (also referred to as the wave cycle 300 of the positive wave) is the positive-amplitude sine wave, while the at least one first wave cycle (also referred to as the first wave cycle) is the negative-amplitude sine wave (see, 304 or 306).

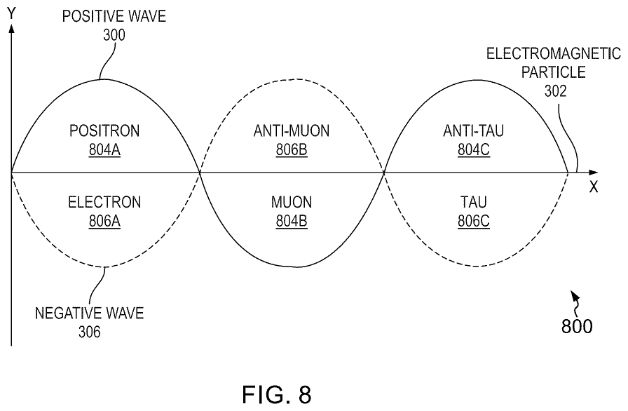

In one embodiment, the first wave cycle (e.g., see, 306) represents the phase-shifted version of the sine wave with the negative amplitude, indicative of the complementary wave function. The first wave cycle also demonstrates the original sine wave (e.g., Yang wave 300) reflected along the x-axis, thus making a distinct first wave cycle (e.g., Yin wave 306) that includes the second set of elementary particles. In another embodiment, the Z-axis wave (e.g., see, 304) represents an anti-matter of the original sine wave. The first wave cycle also demonstrates the original sine wave (e.g., Yang wave or wave cycle 300) reflected along the X-axis, thus making a distinct X-axis wave 306 (e.g., Yin wave) that includes a set of elementary particles. The analysis unit 110 can use at least one of the first wave cycle (i.e., 306) or the X-axis wave (e.g., see, 306) for analysis purposes. For explanatory purposes of this disclosure, the first wave cycle 306 is considered by the analysis unit 110 for analysis. Each of the wave cycle 300 and the first wave cycle 306 have at least one elementary particle. The Standard Model categorizes elementary particles into fermions (such as quarks), bosons (force carriers), and leptons each particle having attributes such as mass, charge, and spin. It should be noted that the wave cycle 300 (e.g., positive wave or negative wave) includes at least first set of three amplitudes and each amplitude has at least one elementary particle. The at least one elementary particle includes at least one of a fermion, a set of bosons, and a set of leptons. The set of leptons includes at least one of an electron, a positron, a muon, an anti-muon, a tau, and an anti-tau particle. The at least one elementary particle is further explained in detail in the present disclosure with reference to FIG. 8 to FIG. 11.

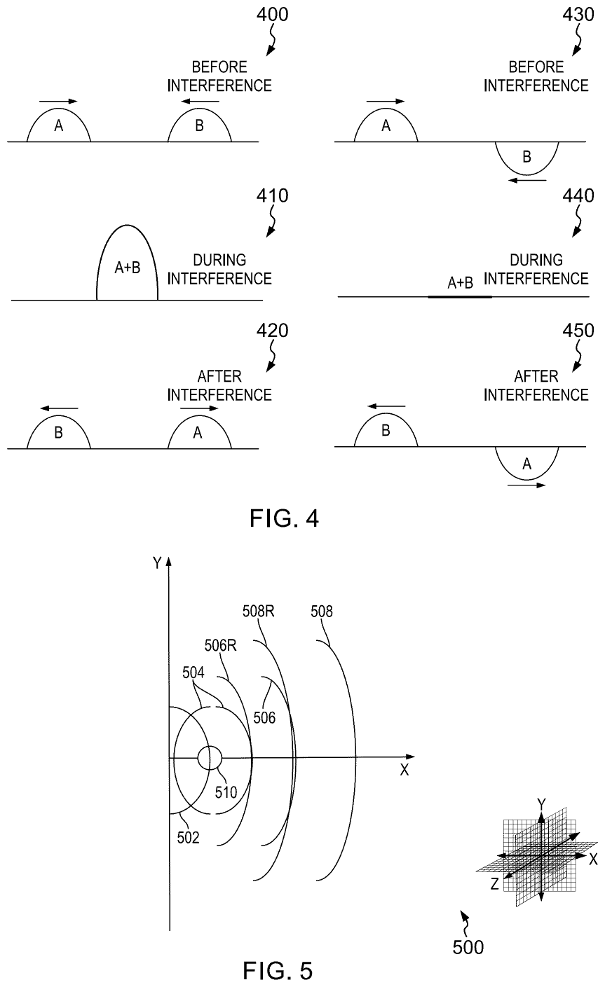

FIG. 4 illustrates representations 400, 410, 420, 430, 440, and 450 for wave interference. The representation 400 depicts two wave patterns A and B of positive amplitude before interference. As the two wave patterns A and B are positive, during interference, the amplitude of the two waves A and B combine and doubles as depicted in the representation 410. After interference, as shown in the representation 420, the position of the two wave patterns A and B are interchanged as compared to the position of the two wave patterns A and B as in the representation 400. The representation 430 depicts two waves A and B of positive amplitude and negative amplitude, respectively before interference. As the two wave patterns A and B are of opposite amplitudes, during interference, the amplitude of the two waves A and B gets cancelled as depicted in the representation 440. After interference, as shown in the representation 450, the position of the two wave patterns A and B are interchanged as compared to the position of the two waves A and B in the representation 430.

In particular, the representations 400, 410, and 420, depict two wave patterns A and B, when intersecting, create regions of constructive interference, and the representations 430, 440, and 450, depict two wave patterns A and B, when intersecting, create regions of destructive interference. The representations 400, 410, 420, 430, 440, and 450 include examples of wave superposition, where wave crests and troughs either align (i.e., constructive interference of coherent wave systems) or misalign (i.e., destructive interference of decoherent wave systems), leading to variations in wave amplitude.

FIG. 5 illustrates a representation 500 for a wave with self-interference. In particular, the representation 500 shows an original first ripple 504 of the wave. Further, the representation 500 shows a reflection of the first ripple 504 off barrier 502, creating a second set of ripples (i.e., a second ripple 506, a reflected second ripple 506R) and a third set of ripples (i.e., a third ripple 508, a reflected third ripple 508R) that emanate from the point of reflection 510. Furthermore, the representation 500 shows interference of the original first ripple 504 and reflected second ripple 506R.

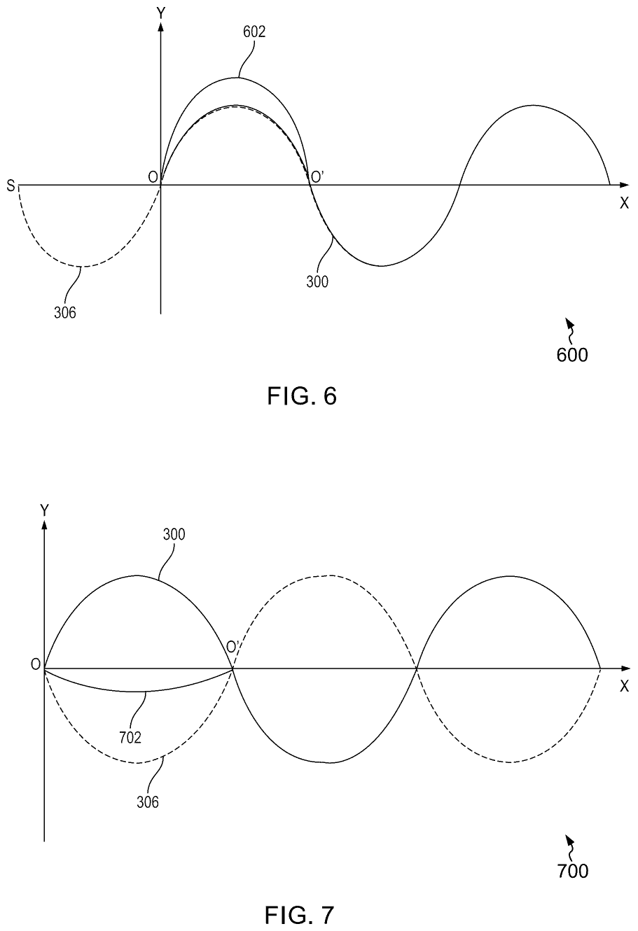

FIG. 6 illustrates a representation 600 of the wave cycle 300 and the first wave cycle 306 with constructive interference, in accordance with embodiments of the present disclosure. The representation 600 shows interaction between elementary particles in each of the wave cycle 300 and the first wave cycle 306. The wave cycle 300 and the first wave cycle 306 are represented along the x-axis, showing the progression of their phases over time. Referring to FIG. 6, the wave cycle 300 is shown as a solid line, and the first wave cycle 306 is shown as a dashed line, propagates along the x-axis. The wave cycle 300 starts at a point S with negative amplitude, while the first wave cycle 306 starts at a point O with positive amplitude. Between points O and O′, the peak of the wave cycle 300 aligns with the peak of the first wave cycle 306. The amplitudes of the wave cycle 300 and the first wave cycle 306 add together, resulting in increased amplitude at these points of intersection, which exemplifies constructive interference, thereby generating the second wave cycle 602. In some embodiments, the representation 600 shows the harmonic balance between the wave cycle 300 and the first wave cycle 306, suggesting that both the wave cycle 300 and the first wave cycle 306 are essential and complementary components of the wave functions.

FIG. 7 illustrates a representation 700 of the wave cycle 300 and the first wave cycle 306 with destructive interference, in accordance with embodiments of the present disclosure. The representation 700 shows interaction between elementary particles in each of the wave cycle 300 and the first wave cycle 306. The wave cycle 300 and the first wave cycle 306 are represented along the x-axis, showing the progression of their phases over time. Referring to FIG. 7, the wave cycle 300 is shown as a solid line, and the first wave cycle 306 is shown as a dashed line, propagates along the x-axis. The wave cycle 300 starts at the point O with positive amplitude and the first wave cycle 306 starts at the point O with negative amplitude. Between points O and O′, the peak of the wave cycle 300 cancels with the peak of the first wave cycle 306. The amplitudes of the wave cycle 300 and the first wave cycle 306 cancel, resulting in decreased amplitude at these points of intersection, which exemplifies destructive interference, thereby generating the second wave cycle 702.

The wave cycle 300 has the first set of elementary particles and the first wave cycle 306 has the second set of elementary particles. The second wave cycle 602 and 702 are generated by the analysis unit 110 of the system 100, by the interference of the wave cycle 300 and the first wave cycle 306. The analysis unit 110 of the system 100 identifies the at least one elementary particle from the first set of elementary particles and the second set of elementary particles based on wave mechanics. The at least one elementary particle includes at least one of a fermion, a set of bosons, and a set of leptons. The set of leptons include the electron/positron, the muon/anti-muon, or the tau/anti-tau particle. The analysis unit 110 determines the energy levels and interaction points of the first set of elementary particles and the second sets of elementary particles by mapping each of the first set of elementary particles to positions on the wave cycle 300 and mapping each of the second set of elementary particles to positions on the first wave cycle 306. The magnitudes of electrical and magnetic forces and/or quantum field(s) interaction(s) resulting from interactions with the quantum field are measured. The wave mechanics in the second wave cycle are determined based on the magnitudes of electrical and mechanical forces measured.

The wave cycle of prior art systems and methods has only two amplitudes (with one full period, t) and hence fails to consider all the elementary particles within the standard model, which may extend the definition of a complete wave cycle. Hence, a full cycle from 0 degrees to 360 degrees is conventionally considered to encompass only 62.5% of a wave's cycle. This indicates that the conventional method of measuring the wave cycle 300 may not account for additional factors.

In particular, the at least one wave cycle 300 shows a single cycle of a wave can be represented in spatial, that is, x versus y, and temporal, that is, t versus y domains. In the spatial domain, one wave cycle is typically shown as the distance over which the wave repeats its shape, known as the wavelength (λ). In the temporal domain, one wave cycle corresponds to the period (t), which is the time it takes for the wave to complete one full oscillation.

FIGS. 8, 10 and 11 illustrate respectively representations 800, 1000, and 1100 depicting temporal modes of the at least one wave cycle 300 of the electromagnetic particle, in accordance with some embodiments of the present disclosure. in the present disclosure, the wave cycle 300 begins at the origin point (0,0) and progresses through one complete oscillation until the waveform returns to the same point in its cycle, which is denoted as one full period, t. The representations 800, 1000 and 1100 uniquely represent 100% of the wave cycle 300, as annotated, as opposed to the conventional representation of the wave cycle 300 which accounts for a lesser percentage of a complete cycle. Compared to the two amplitude wave cycle representation of the wave cycle 300 (takes 720 degrees), the three amplitude representation of the wave cycle 300 takes only 306 degrees to return to the origin point (0,0). In particular, the three amplitude representation of the at least one wave cycle 300 (see representations 800, 1000, and 1100 of FIGS. 8, 10, and 11) shows that the 360 degree turn for the at least one wave cycle represents 100% of the complete wave cycle, which facilitates a more comprehensive and accurate depiction of a behavior of a wave over time and space. The three amplitude representation of the at least one wave cycle 300 shows a redefined baseline for what constitutes the start and end points of the wave cycle 300 with consideration of all wave components and all elementary particles associated with the complete wave cycle. Conventionally, the definition of a full wave cycle did not consider all components of a wave and all elementary particles within the standard model. The scientific understanding of the “spin” that a particle possesses is related to its intrinsic angular momentum, however, in actuality, the particle is not spinning. To understand that a particle has angular momentum without actually spinning, the conventional cycle definition was used. However, with the conventional cycle definition, 720 degrees must be completed in order for a particle to get back to its start position, and a particle can have a spin value of either clockwise (½) or counterclockwise (−½).

By referencing the elementary wave diagrams, it can be inferred the intrinsic spin comes from, depending on if the particle is positioned going “uphill” or “downhill”. The uphill portion results in a counterclockwise spin, where downhill results in a clockwise spin. In order for an object to return to its original position, it must rotate 360 degrees along a given rotational access. Conventionally, if an object is rotated 720 degrees, the same result may be obtained. Therefore, in an embodiment, only one, 360 degree rotation may enable the object to return to the start position. Therefore, it may be appreciated that in accordance with embodiments of the present disclosure, only 360 degrees turn is required to return to the starting point, versus an additional 360 according to the conventional definition.

FIG. 8 illustrates representation 800 of the at least one of the electromagnetic particle 302 and the quantum field having the wave cycle 300 and the first wave cycle, each having at least one elementary particle, in accordance with some embodiments of the present disclosure. In FIG. 8, the wave cycle 300 is part of the positive wave (also referred to as “Yang wave”), while the first wave cycle 306 is part of the negative wave (also referred to as “a Yin wave”), each having at least one elementary particle. Alternately, the wave cycle 300 may be part of the negative wave (also referred to as “a Yin wave”), while the first wave cycle 306 may be part of the positive wave (also referred to as “Yang wave”) each having the at least second set of three amplitudes. Each amplitude of the at least second set of three amplitudes has the at least one elementary particle, in accordance with some embodiments of the present disclosure.

In the explanatory embodiments, it is considered that the electromagnetic particle has the wave cycle 300 and the first wave cycle 306 is generated for interference by the system 100. In some embodiments, the electromagnetic particle and/or quantum field(s) fluctuation(s) has both the wave cycle 300 and the first wave cycle 306. In such scenarios, the wave cycle 300 of the positive wave and the first wave cycle 306 of the negative wave result from an interaction of the electromagnetic particle 302 and the quantum field (e.g., Higgs field). Due to the oscillation of the wave cycle 300 of the positive wave (i.e., positive monopole) and the first wave cycle 306 of the negative wave (i.e., negative monopole), the electromagnetic particle 302 itself is neutrally charged. Referring to FIG. 8, the representation 800 shows at least one wave cycle 300 within a defined radius associated with the electromagnetic particle 302 such as photon (or gluon) and the underlying quantum field. As shown, the wave cycle 300 and the first wave cycle 306 are presented within the spatial limitations imposed by photon (or gluon) interactions, suggesting a dual wave configuration. The dual wave configuration encompasses aspects of wave-particle duality, particle-wave interactions, quantum superposition, quantum tunneling, and quantum entanglement. In particular, the dual wave configuration symbolizes the quantum superposition principle, where each of the elementary particles may exist in multiple states simultaneously until measured. The spatial domain, delineated by the photon's radius and the underlying quantum field in comparison to the described dataset (described later), has specific properties that monitor the behavior of the waves and give rise to mass, contributing to a deeper understanding of quantum mechanisms.

It may be appreciated that photons are responsible for the electromagnetic force. Photons are most commonly referred to as light. When elementary waves interact, especially in small systems (such as an atom or quantum level), it results in electrical and magnetic forces. The larger the system, the larger the electrical and magnetic forces can be observed.

It may be appreciated that gluons are responsible for the strong nuclear force (the force that holds an atom together). The waves therefore must be fully contained within the radius of gluons in order to make an atom (not shown in the figures). It can be liberally represented as a horizontal plane or x-axis. When a portion of a wave is able to escape the radius to which the gluon keeps everything together, energy is emitted. When more portions of a wave (or a full wave) contained within the gluon radius escape, a massive amount of energy is released.

The representation 800 is the wave cycle 300 that is a positive wave cycle with the at least first set of three amplitudes, each amplitude (i.e., first amplitude, second amplitude, and third amplitude) having the first set of elementary particles. The first amplitude of the at least first set of three amplitudes of the wave cycle 300 includes a positron 804A, the second amplitude includes a muon 804B, and the third amplitude includes an anti-tau 804C. The first wave cycle 306 of the negative wave with the at least second set of three amplitudes, each amplitude (i.e., first amplitude, second amplitude, and third amplitude) has the second set of elementary particles. The first amplitude includes an electron 806A, the second amplitude includes an anti-muon 806B, and the third amplitude includes a tau particle 806C. The positron 804A, the muon 804B, the anti-tau 804C, the electron 806A, the anti-muon 806B, and the tau particle 806C are collectively referred to as leptons.

In an alternate embodiment the wave cycle 300 may be the negative wave with the at least first set of three amplitudes, each amplitude (i.e., first amplitude, second amplitude, and third amplitude) having the first set of elementary particles. The first amplitude includes the electron 806A, the second amplitude includes the anti-muon 806B, and the third amplitude includes the tau particle 806C. The first wave cycle 306 of the positive wave with the at least second set of three amplitudes, each amplitude (i.e., first amplitude, second amplitude, and third amplitude) has the second set of elementary particles. The first amplitude includes the positron 804A, the second amplitude includes the muon 804B, and the third amplitude includes the anti-tau 804C.

Further, FIG. 8 shows a direct correlation between the electron 806A, the anti-muon 806B, and the tau particle 806C in the elementary standard model and one of three waveforms. Each amplitude of the at least second set of three amplitudes of the first wave cycle 306 of the negative wave (or the wave cycle 300 of the positive wave) is determined based on the respective masses that arise from interaction with the quantum field (e.g., Higgs field). The specific mass values are therefore correlated to the respective degrees and Circle of Fifths rounds as determined within the given dataset.

New particles may be identified as they possess the underlying mathematical layout of the quantum field. The mathematical layout of the underlying quantum field is determined through mathematical application of the Circle of Fifths rounds to degrees, or radians, of a circle, as shown as follows. The Circle of Fifths is a mathematical ratio of 3/2, or 1.5, that is attributed to harmonious frequencies. An initial degree value (degᵢ) representing a degree of rotation is converted into an initial radians value (radᵢ) by multiplying the degᵢ by (3.14/180) where “3.14” represents “π: and “180” represents “180 degrees” as shown in Eqn. (1). For instance, 60 degrees is equivalent to 1.04719755133333 radians.

$$Initial degree value ( {deg}_{i} ) = Initial radians value ( {rad}_{i} ) \times ( \frac{3.14}{180} ) \qquad Eqn . ( 1 )$$

The obtained initial radians value (radᵢ) is multiplied by 1.5 to yield a round 1 term (R₁) as shown in Eqn. (2):

$${R}_{1} = {rad}_{i} \times 1.5 \qquad Eqn . ( 2 )$$

For instance, for a radᵢ of 1.04719755133333 radians, R₁ was obtained from Eqn. (2) is 1.57079632700000001 radians.

The preceding round term (i.e., the R₁) is then multiplied again by the Circle of Fifths value of 1.5 to yield a round 2 term (i.e., R₂) as shown in Eqn. (3):

$${R}_{2} = {R}_{1} \times 1.5 \qquad Eqn . ( 3 )$$

For instance, for R₁ of 1.57079632700000001, R₂ obtained from Eqn. (3) is 2.3561944905 radians.

The Circle of Fifths is continued until 12 rounds are completed, with the proceeding round term being multiplied by the ratio 3/2, that is, 1.5 as shown in Eqn. (4) and Eqn. (5).

$${R}_{3} = {R}_{2} \times 1.5 \qquad Eqn . ( 4 )$$

$${R}_{12} = {R}_{11} \times 1.5 \qquad Eqn . ( 5 )$$

It is important to note the Circle of Fifths rounds continues till infinity, however, the system may be stopped after about 12 rounds. The same is true for ascending degrees of a circle as degrees of the circle also continue till infinity unless calculations are limited to a user desired input.

The Circle of Fifths rounds provide a dataset that is a large as output that represent layout from which quantum field fluctuation arises, thereby corroborating with results for the elementary particles carrying mass obtained from the Standard Model.

The dataset obtained from the Circle of fifths rounds essentially represents the layout of observable elementary particles and/or underlying quantum field fluctuation(s) before undergoing the process in which the said observable elementary particles obtain respective masses. The dataset, therefore, represents layout of masses for the said observable elementary particles. The data set may be attributed to quantum field interactions (e.g., Higgs field that is thought to be the field in which all the elementary particles in the universe obtain mass). Through interaction with the quantum field, each of the elementary particles is capable of acquiring mass.

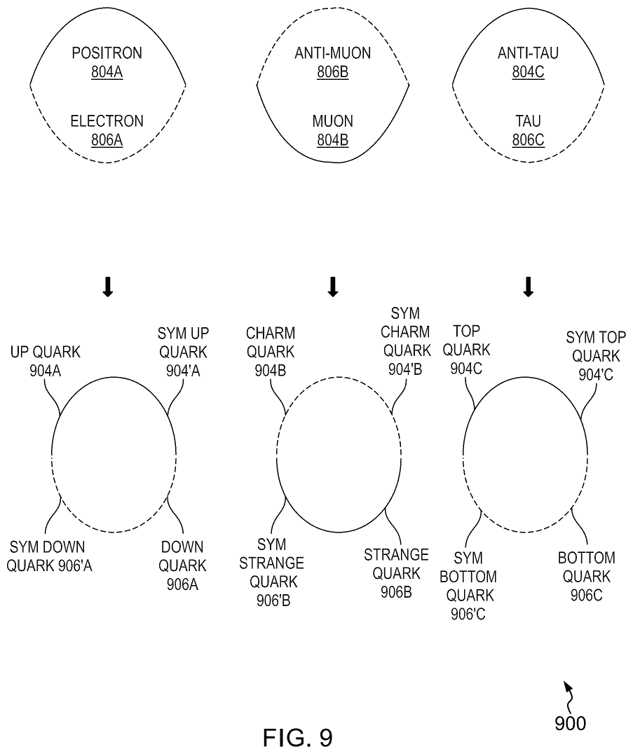

FIG. 9 illustrates representation 900 of elementary quark particles and their symmetric counterparts present in the wave cycle 300 and the first wave cycle 306, in accordance with some embodiments of the present disclosure. The set of leptons shown in FIG. 8 are further made up of the at least one fermion that includes one or more quark particles. For example, the positron 804A includes an up quark 904A and a symmetrical up quark 904′A (also referred to as “a sym up quark 904′A), the muon 804B includes a symmetrical strange quark 906′B (also referred to as “a sym strange quark 906′B”) and a strange quark 906B, and the anti-tau 804C includes a top quark 904C and a symmetrical top quark 904′C (also referred to as “a sym top quark 904′C”). In another instance, the electron 806A includes a symmetrical down quark 906′A (also referred to as “a sym down quark 906′A”) and a down quark 906A, the anti-muon 806B includes a charm quark 904B and a symmetrical charm quark 904′B (also referred to as “a sym charm quark 904′B”), and the tau particle 806C includes a symmetrical bottom quark 906′C (also referred to as “a sym bottom quark 906′C”) and a bottom quark 906C. The representation 900 shows a direct correlation between quarks in the elementary standard model (e.g., up, down, strange, charm, top, bottom) and one of the two waveforms. In some embodiments, the elementary particles, as defined in the standard model, exhibit behaviors and properties that correspond to one of the two waveforms. It is important to note quark components of the two waveforms may be fractals off the underlying two waveforms.

The electromagnetic particle 302 follows the principle of symmetry. In particular, the representation 800 depicts a symmetrical pattern, where a solid line represents an original object or pattern, and a dashed line represents a corresponding mirror image. It may be appreciated that this symmetry visualization is essential for understanding the symmetric properties and behaviors of elementary particles and waves in the proposed mechanism, particularly in relation to wave-particle interactions and their symmetric or antisymmetric nature in three-dimensional space. The symmetric properties include exhibition of spin-parity asymmetry, and with the interactions with bosons allow for maintenance and propagation of the respective waves.

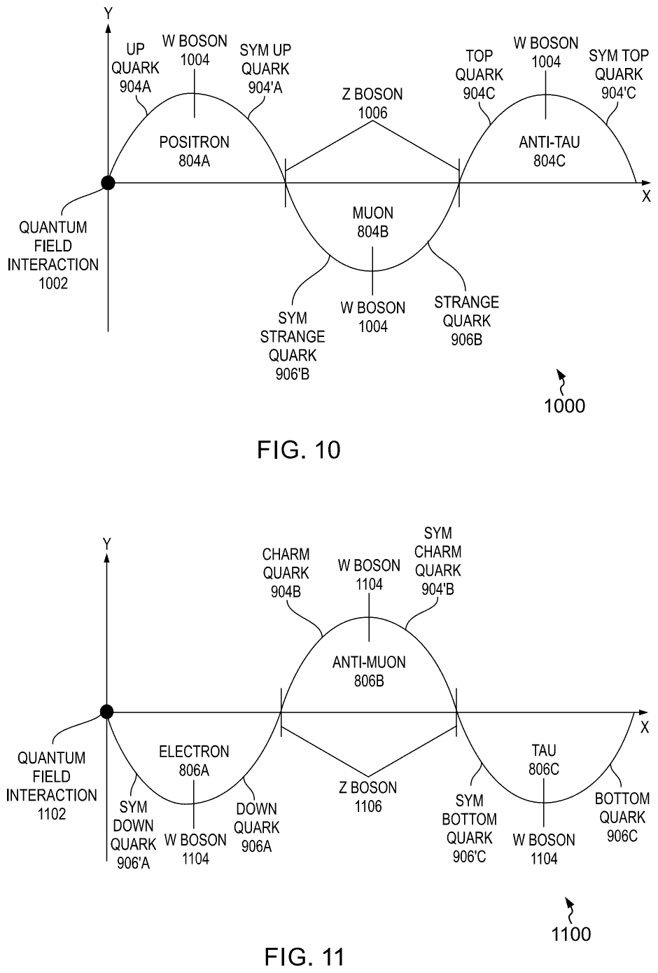

FIG. 10 illustrates a representation 1000 of the first set of elementary particles resulting from interaction (e.g., wave cycle 300) 1002 with underlying quantum field(s), in accordance with embodiments of the present disclosure. The representation 1000 shows from z-axis view of one full cycle of the wave cycle 300 of the positive wave (Yang), in accordance with embodiments of the present disclosure. In particular, the wave cycle 300 of the positive wave has a full cycle of a wave with the positive amplitude (e.g., a sine wave with positive amplitude). The at least one elementary particle including at least one of fermions (such as one or more quarks), the set of bosons (i.e., the W(±) boson and the Z boson), and the set of leptons (i.e., the electron/positron, the muon/anti-muon, or the tau/anti-tau particle) are mapped to positions on each amplitude of the at least first set three amplitudes of the wave cycle and the at least second set of three amplitudes of the first wave cycle, depicting their energy levels, orientation, or interaction points with the quantum field (i.e., Higgs field) as represented by the given dataset.

The representation 1000 shows that the wave peaks and troughs are annotated with labels corresponding to the first set of elementary particles as they pertain to the wave cycle 300 of the positive wave (Yang). The representation 1000 indicates a unique correlation between the waveform of the wave cycle 300 of the positive wave and the properties or behaviors of the annotated first set elementary particles. The at least one elementary particle of the first set of elementary particles cycle of the wave cycle 300 includes at least one of a W(+) boson 1004 and a Z boson 1006. For instance, the peak of the wave is labeled with the W(±) Boson 1004, a mediator of the weak force.

The foundational building blocks of the wave cycle 300 of the positive wave, are three quarks: the up quark 904A, the strange quark 906B, and the top quark 904C. For instance, the at least one elementary particle of the wave cycle 300 includes at least one of the up quark 904A, the symmetrical up quark 904′A, the symmetrical strange quark 906′B, the strange quark 906B, the top quark 904C, and the symmetrical top quark 904′C. The W(±) boson 1004 connects the symmetrical portion of the above three quarks (i.e., the up quark 904A, the strange quark 906B, and the top quark 904C) so that their mirror images (i.e., the symmetrical up quark 904′A, the symmetrical strange quark 906′B, and the symmetrical top quark 904′C) are identical in a vertical manner and position In particular, the W± boson 1204 connects the up quark 904A to the symmetrical up quark 904′A, the symmetrical strange quark 906′B to the strange quark 906B, and the top quark 904C to the symmetrical top quark 904′C, thereby causing interaction of the first set of elementary particles in the first wave cycle 306 along a vertical plane. The symmetric properties include the exhibition of spin-parity asymmetry between quark and its sym quark, with interactions of bosons allowing for maintenance and propagation of the respective waves. It is important to note the various quarks comprised within the wave may be fractals off the underlying waveform.

Further, the Z Boson 1006 helps connect the different quarks together. In particular, the Z Boson connects the symmetrical up quark 904′A to the symmetrical strange quark 906′B, and the strange quark 906B to the top quark 904A, thereby causing the interaction and propagation of the first set of elementary particles of the wave cycle 300 along a horizontal plane.

FIG. 11 illustrates a representation 1100 of the second set of elementary particles resulting due to interaction (e.g., first wave cycle 306) 1102 with underlying quantum field(s), in accordance with embodiments of the present disclosure. The representation 1100 from z-axis view of 1 full cycle of the negative wave (Yin) 306 (or the first wave cycle 306), in accordance with embodiments of the present disclosure. In particular, the first wave cycle 306 has a full cycle of a wave with the negative amplitude (e.g., sine wave with negative amplitude as shown in FIG. 11)

Referring to FIG. 11, the representation 1100 shows that the wave peaks and troughs are annotated with labels corresponding to the second set elementary particles as they pertain to the first wave cycle 306 of the negative wave. The representation 1100 indicates a unique correlation between the waveform of the first wave cycle 306 of the negative wave and the properties or behaviors of the annotated second set elementary particles. The at least one elementary particle of the second set of elementary particles cycle of the first wave cycle 306 includes at least one of the W(±) boson and the Z boson. For instance, the at least one elementary particle of the first wave cycle 306 includes at least one of the symmetrical down quark 906′A, the down quark 906A, the charm quark 904B, the symmetrical charm quark 904′B, the bottom quark 906C, and the symmetrical bottom quark 906′C (as shown in FIG. 11). The W(±) boson 1104 connects the symmetrical down quark 906′A with the down quark 906A, the symmetrical charm quark 904′B with the charm quark 904B, and the symmetrical bottom quark 906′C with the bottom quark 906C, thereby causing interaction of the second set of elementary particles in the first wave cycle 306 along a vertical plane. The Z Boson 1106 connects the down quark 906A to the charm quark 904B, and the symmetrical charm quark 904′B to the symmetrical bottom quark 906′C, thereby causing the interaction of the second set of elementary particles of the first wave cycle 306 along a horizontal plane. The symmetric properties include exhibition of spin-parity asymmetry between quark and its sym quark, with interactions of bosons allowing for maintenance and propagation of the respective waves. It is important to note the various quarks comprised within the wave may be fractals off the underlying waveform.

The presence of symmetrical quarks and bosons within this model implies a deeper level of symmetry in particle interactions, suggesting a unified field theory that may combine the discrete particles with wave-like behaviors.

In an embodiment, the Z Boson 1006 and the Z Boson 1106, that is an elementary particle within the standard model known for mediating the weak nuclear force, is a central force that interacts with the first wave cycle 306 of the negative wave and the wave cycle 300 of the positive wave. These waves symbolize the dual nature of elementary particles as they exhibit wave-like behavior.

As the Z Boson 1006 and the Z boson 1106 operate in the vertical dimension, the W(±) Boson 1004 and the W(±) boson 1104 function in a similar capacity but in the horizontal plane, depicting the movement of the wave cycle 300 of the positive wave and the first wave cycle 306 of the negative wave in a forward and a backward direction. This model may point to a deeper interaction mechanism where bosons are not merely force carriers but also key to maintaining the structure and interaction of waveforms at the quantum level. In an embodiment, both the W(±) boson (1004, 1104) and the Z Boson (1006, 1106) hold together different components of individual waves (i.e., the positive wave and the negative wave), in order to keep wave(s) together.

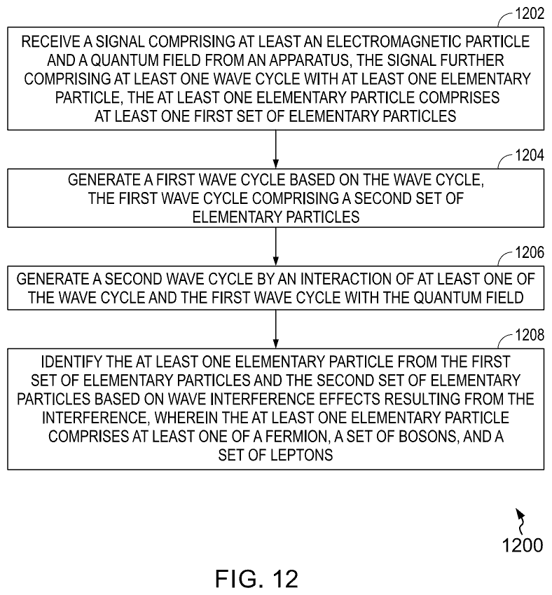

FIG. 12 illustrates a schematic flowchart of an assay method 1200 for detection and identification at least one elementary particle, in accordance with an embodiment of the present disclosure. Further, for ease of explanation, according to various embodiments in the present disclosure, the process may be implemented by a processor 118 of an analysis unit 110 in a system 100, as described with reference to FIG. 1. The assay method 1200 illustrated in the flowchart may start from step (1202).

At step 1202, receiving of a signal including an electromagnetic particle 302 and/or quantum field(s) fluctuation(s) from an apparatus 102 is carried out. The signal further includes at least one wave cycle with at least one elementary particle. The at least one elementary particle includes at least one first set of elementary particle.

At step 1204, the generation of a first wave cycle 306 is done based on the wave cycle 300. The first wave cycle 306 includes a second set of elementary particles.

At step 1206, the generation of a second wave cycle is done by an interference of the wave cycle 300 and the first wave cycle 306.

At step 1208, identification of the at least one elementary particle from the first set of elementary particles and the second set of elementary particles is carried out based on wave mechanics. The at least one elementary particle includes at least one of a fermion, a set of bosons, and a set of leptons. The set of leptons includes at least one of an electron, a positron, a muon, an anti-muon, a tau, and an anti-tau particle.

The assay method 1200 may further include a step of determination of energy levels and interaction points of the first set of elementary particles and the second sets of elementary particles by mapping each of the first set of elementary particles to positions on the wave cycle and mapping each of the second set of elementary particles to positions on the first wave cycle. The assay method 1200 may also include a step of measuring magnitudes of electrical and magnetic forces and/or quantum field(s) fluctuations resulting from interactions with the quantum field (e.g., Higgs field). Further, the assay method may include a step of determining the wave mechanics in the second wave cycle based on the magnitudes of electrical and mechanical forces measured.

Therefore, the embodiments of the present disclosure may be applied to quantum systems such as protons, neutrons, and electrons, or the like. For example, from current data acquired via particle colliders, it may be known that a proton contains two up quarks and one down quark, however this only accounts for 1% of a proton's mass. In accordance with embodiments of the present disclosure, the missing components of a proton can be found to account for 100% of a proton's mass. Accordingly, this cascade effect of information can continue and be applied to molecules, DNA, species, etc., and underlay a broad array of applications, potentially revolutionizing apparatuses, devices, systems, and methods or processes across multiple scales. By providing a fundamental understanding of quantum interactions, it may enable precise manipulation of quantum states, leading to advancements such as targeted genetic repair, gravity manipulation for flight, and enhanced space exploration technologies.

Although various exemplary embodiments of the disclosure are described herein in a language specific to structural features and/or methodological acts, the subject matter defined in the appended claims is not necessarily limited to the specific features or acts described above. Rather, the specific features and acts described above are disclosed as exemplary forms of implementing the claims.

What is claimed is:

1. An assay method for identifying at least one elementary particle generated in an apparatus, the method comprising:
receiving a signal comprising at least one of an electromagnetic particle and a quantum field from the apparatus, the signal further comprising at least one wave cycle with the at least one elementary particle, the at least one wave cycle comprising at least first set of three amplitudes, the at least one elementary particle in each amplitude of the at least first set of three amplitudes comprising at least one first set of elementary particles;
generating a first wave cycle comprising at least second set of three amplitudes based on the wave cycle, the at least one elementary particle in each amplitude of the at least second set of three amplitudes comprising at least one second set of elementary particles;
generating a second wave cycle by an interaction of at least one of the wave cycle and the first wave cycle with the quantum field;
identifying the at least first set of three amplitudes of the wave cycle and the at least second set of three amplitudes of the first wave cycle based on at least one of the second wave cycle and the interaction of the first wave cycle and the quantum field; and
identifying the at least one elementary particle from each amplitude of the at least first set of three amplitudes of the wave cycle and each amplitude of the at least second set of three amplitudes of the first wave cycle in the first set of elementary particles and the second set of elementary particles based on wave interference effects resulting from the interference, wherein the at least one elementary particle comprises at least one of a fermion, a set of bosons, and a set of leptons.

2. The method as claimed in claim 1, further comprising:
determining energy levels and interaction points of the first set of elementary particles and the second sets of elementary particles by mapping each of the first set of elementary particles to positions on the wave cycle and mapping each of the second set of elementary particles to positions on the first wave cycle;
measuring magnitudes of electrical and magnetic forces resulting from quantum field interactions; and
determining the wave mechanics in the second wave cycle based on the magnitudes of electrical and mechanical forces measured.

3. The method as claimed in claim 1, wherein the at least one wave cycle results from an interaction of the electromagnetic particle and the quantum field.

4. The method as claimed in claim 1, wherein,
the wave cycle comprises a wave of a full cycle with at least a positive amplitude and a negative amplitude, and
the first wave cycle comprises a reflected wave derived from the wave cycle, the reflected wave comprising the full cycle with at least the positive amplitude and the negative amplitude.

5. The method as claimed in claim 1, wherein each amplitude of the at least first set of three amplitudes and the at least second set of three amplitudes comprises the at least one elementary particle of the first set of elementary particles, the at least one elementary particle comprises at least one of the set of bosons.

6. The method as claimed in claim 1, wherein each amplitude of the at least first set of three amplitudes and the at least second set of three amplitudes comprises the at least one elementary particle of the wave cycle of a positive amplitude, the at least one elementary particle of the wave cycle of a positive amplitude comprises the at least one fermion, a set of bosons and a set of leptons.

7. The method as claimed in claim 6, wherein the at least one fermion comprises at least one of an up quark, a symmetrical up quark, a symmetrical strange quark, a strange quark, a top quark, a symmetrical top quark.

8. The method as claimed in claim 6, wherein the set of leptons comprises an positron, a muon, and an anti-tau particle.

9. The method as claimed in claim 6, wherein the set of bosons comprises a W(±) boson and a Z boson.

10. The method as claimed in claim 9, wherein the W(±) boson connects the symmetrical up quark, the symmetrical strange quark, and the symmetrical top quark with the up quark, the strange quark, and the top quark, respectively, thereby causing interaction of the first set of elementary particles in the first wave cycle along a vertical plane.

11. The method as claimed in claim 9, wherein the Z Boson connects the symmetrical up quark to the symmetrical strange quark, and the strange quark to the top quark, thereby causing the interaction of the first set of elementary particles of the first wave cycle along a horizontal plane.

12. The method as claimed in claim 1, wherein each amplitude of the at least first set of three amplitudes comprises the at least one elementary particle of the wave cycle of a negative wave, the at least one elementary particle of the wave cycle of a negative wave comprises the at least one fermion, a set of bosons, and a set of leptons.

13. The method as claimed in claim 12, wherein the at least one fermion comprises at least one of a symmetrical down quark, a down quark, a charm quark, a symmetrical charm quark, a bottom quark, and a symmetrical bottom quark.

14. The method as claimed in claim 12, wherein the set of leptons of the comprises an positron, an anti-muon, and a tau particle.

15. The method as claimed in claim 12, wherein the set of bosons comprises a W(±) boson and a Z boson.

16. The method as claimed in claim 15, wherein the W(±) boson connects the symmetrical down quark, the symmetrical charm quark, and the symmetrical bottom quark with the down quark, the charm quark, and the bottom quark, respectively, thereby causing interaction of the second set of elementary particles in the first wave cycle along a vertical plane.

17. The method as claimed in claim 15, wherein the Z Boson connects the down quark to the charm quark, and the symmetrical charm quark to the symmetrical bottom quark, thereby causing the interaction of the second set of elementary particles of the first wave cycle along a horizontal plane.

18. The method as claimed in claim 1, wherein the wave mechanics comprise effects due to constructive interference, destructive interference, and self-interference of the wave cycle and the quantum field.

19. The method as claimed in claim 1, wherein the wave cycle and the first wave cycle are each generated with a redefined baseline with consideration of all wave components and all elementary particles associated with the at least one wave cycle.

20. The method as claimed in claim 1, wherein the wave cycle and the first wave cycle are contained within a defined radius associated with the electromagnetic particle to form a dual wave configuration, the dual wave configuration encompasses aspects of wave-particle duality, particle-wave interactions, quantum superposition, quantum tunneling, and quantum entanglement.

21. A system, comprising:
an apparatus comprising a particle source, a detector, and a transmitter, the particle source is configured to generate a signal comprising at least one of an electromagnetic particle and a quantum field in a predefined orientation; and
an analysis unit comprising:
a memory for storing instructions;
a control unit equipped with a display controller, a display unit, a non-volatile storage unit, an input/output (I/O) controller and one or more I/O devices; and
a processor configured for executing the instructions, the processor causes the system, at least in part, to:
receive the signal comprising at least one of the electromagnetic particle and the quantum field from the apparatus, the signal further comprising at least one wave cycle with at least first set of three amplitudes, the at least one elementary particle in each amplitude of the at least first set of three amplitudes comprising at least one of a first set of elementary particles;
generate a first wave cycle with at least second set of three amplitudes based on the wave cycle, the at least one elementary particle in each amplitude of the at least second set of three amplitudes comprising at least one of a second set of elementary particles;
generate a second wave cycle by interaction of at least one of the wave cycle and the first wave cycle with the quantum field;
identify the at least first set of three amplitudes of the wave cycle and the at least second set of three amplitudes of the first wave cycle based on at least one of the second wave cycle and the interaction of the first wave cycle and the quantum field; and
identify at least one elementary particle from each amplitude of the at least first set of three amplitudes of the wave cycle and each amplitude of the at least second set of three amplitudes of the first wave cycle in the first set of elementary particles and the second set of elementary particles based on wave mechanics, wherein the at least one elementary particle comprises at least one of a fermion, a set of bosons, a set of leptons.

22. The system as claimed in claim 21, wherein the processor further causes the system, at least in part, to:
determine energy levels and interaction points of the first set of elementary particles and the second sets of elementary particles by mapping each of the first set of elementary particles to positions on the wave cycle and mapping each of the second set of elementary particles to positions on the first wave cycle;
measure magnitudes of electrical and magnetic forces resulting from interactions with the quantum field; and
determine wave mechanics in the second wave cycle based on the magnitudes of electrical and mechanical forces measured.

23. The system as claimed in claim 21, wherein,
the particle source is a continuous wave particle source configured to produce at least one of the electromagnetic particle and the quantum field,
the detector is configured to convert an at least one wave cycle contained within a defined radius associated with the at least one of the electromagnetic particle and the quantum field into an electronic detection signal, and
the transmitter coupled to the detector is configured to transmit, in a flow, an electronic detection signal as a wave cycle input to the control unit.

24. The system as claimed in claim 21, wherein
the non-volatile storage unit coupled with a network interface is accessible to the processor for data processing;
the input/output (I/O) controller is configured to:
receive the wave cycle input from the transmitter of the apparatus through the one or more I/O devices, and send information to the processor for data processing, and
receive the wave cycle output from the processor and send to the display controller through the one or more I/O devices; and
the display controller is configured to display the wave output in the display unit.

25. The system as claimed in claim 21, wherein the electromagnetic particle is a photon and the quantum field is an underlying quantum field.

26. The system as claimed in claim 21, wherein the set of leptons comprises at least one of an electron, a positron, a muon, an anti-muon, a tau, and an anti-tau particle.
